(19) United States
(12) Patent Application Publication
(10) Pub. No.: US 2009/0200539 A1
(43) Pub. Date: Aug. 13, 2009

(54) Composite Nanorod-Based Structures for Generating Electricity

(76) Inventor: Pengfei Qi, Menlo Park, CA (US)

Correspondence Address: MORGAN, LEWIS & BOCKIUS, LLP. (PA), 2 PALO ALTO SQUARE, 3000 EL CAMINO REAL, PALO ALTO, CA, 94306, US

(21) Appl. No.: 12/368,250

(22) Filed: Feb. 9, 2009

Related U.S. Application Data
(60) Provisional application No. 61/065,195, filed on Feb. 8, 2008.

(51) Int. Cl. H01L 29/06; H01L 21/20

(52) U.S. Cl. 257/14; 438/478; 257/E29.025; 257/E21.09; 977/762

(57) ABSTRACT

Composite nanorod-based structures for generating electricity are disclosed. One embodiment is an article of manufacture that includes a first layer with an array of nanowires and a dielectric material. The nanowires include: a core semiconducting region with a first type of doping; a shell semiconducting region with a second type of doping; and a junction region between the core semiconducting region and the shell semiconducting region. The first type of doping is different from the second type of doping. The shell region length is less than the core region length. The shell semiconducting region surrounds a portion of the core semiconducting region over a length of the core semiconducting region corresponding to the junction region length. A second layer comprising a conducting material contacts the top surface of the first layer. A third layer comprising a conducting material contacts the bottom surface of the first layer.

### RELATED APPLICATIONS

This application claims priority to U.S. Provisional Patent Application No. 61/065,195, “Composite Nanorod-Based Structures and Methods for Generating Electricity,” filed Feb. 8, 2008, which is incorporated by reference herein in its entirety.

### TECHNICAL FIELD

The disclosed embodiments relate generally to structures for photovoltaic energy production. More particularly, the disclosed embodiments relate to structures that use nanorod-based composites to generate photovoltaic energy.

### BACKGROUND

Considerable effort has been put into developing materials and structures for use as solar cells, with limited success. Thus, there remains a need to develop new structures for generating photovoltaic energy that are efficient, low cost, stable, and non-toxic.

### SUMMARY

The present invention addresses the problems described above by providing composite nanorod-based structures for generating photovoltaic energy and methods for making these structures.

One aspect of the invention involves an article of manufacture that includes a first layer with a top surface and a bottom surface. The first layer includes an array of nanowires and a dielectric material. The nanowires in the array of nanowires include: a core semiconducting region with a first type of doping and a core region length; a shell semiconducting region with a second type of doping and a shell region length; and a junction region between the core semiconducting region and the shell semiconducting region with a junction region length. The first type of doping is different from the second type of doping. The shell region length is less than the core region length. The shell semiconducting region surrounds a portion of the core semiconducting region over a length of the core semiconducting region corresponding to the junction region length. The article of manufacture also includes a second layer contacting the top surface of the first layer. The second layer comprises a conducting material. The article of manufacture also includes a third layer contacting the bottom surface of the first layer. The third layer comprises a conducting material.

Another aspect of the invention involves an article of manufacture that includes a freestanding multi-layer composite. The freestanding multi-layer composite includes a first layer with a top surface and a bottom surface. The first layer comprises an array of nanowires and a dielectric material. The nanowires in the array of nanowires include: a core semiconducting region with a first type of doping and a core region length; a shell semiconducting region with a second type of doping and a shell region length; and a junction region between the core semiconducting region and the shell semiconducting region with a junction region length. The first type of doping is different from the second type of doping. The shell region length is less than the core region length. The shell semiconducting region surrounds a portion of the core semiconducting region over a length of the core semiconducting region corresponding to the junction region length. The article of manufacture also includes a second layer contacting the top surface of the first layer comprising a conducting material, and a third layer contacting the bottom surface of the first layer comprising a conducting material.

Another aspect of the invention involves an article of manufacture that includes a freestanding stack of composite films. At least some of the composite films in the stack of composite films include a first layer, a second layer, and a third layer. The first layer has a top surface and a bottom surface. The first layer comprises an array of nanowires and a dielectric material. Nanowires in the array of nanowires include: a core semiconducting region with a first type of doping and a core region length; a shell semiconducting region with a second type of doping and a shell region length; and a junction region between the core semiconducting region and the shell semiconducting region with a junction region length. The first type of doping is different from the second type of doping. The shell region length is less than the core region length. The shell semiconducting region surrounds a portion of the core semiconducting region over a length of the core semiconducting region corresponding to the junction region length. The second layer contacts the top surface of the first layer and comprises a conducting material. The third layer contacts the bottom surface of the first layer and comprises a conducting material.

Another aspect of the invention involves a method that includes: forming an array of nanowires on a substrate. The method also includes, for a plurality of nanowires in the array of nanowires: forming a core semiconducting region with a first type of doping, and forming a shell semiconducting region with a second type of doping. The method also includes: embedding a first portion of the nanowires in a first dielectric layer; embedding a second portion of the nanowires in a first conducting layer, wherein the second portion of the nanowires is adjacent to the first portion of the nanowires; embedding a third portion of the nanowires in a second dielectric layer, wherein the third portion of the nanowires is adjacent to the second portion of the nanowires; removing the shell semiconducting region from a fifth portion of the nanowires; embedding at least some of the fifth portion of the nanowires in a third dielectric layer; embedding at least some of the fifth portion of the nanowires in a second conducting layer, wherein the second conducting layer is on top of the third dielectric layer; and removing the substrate.

Another aspect of the invention involves a method that includes: forming an array of nanowires on a substrate. The method also includes, for a plurality of nanowires in the array of nanowires: forming a core semiconducting region with a first type of doping, and forming a shell semiconducting region with a second type of doping. The method also includes: embedding a first portion of the nanowires in a first masking layer; embedding a second portion of the nanowires in a first conducting layer, wherein the second portion of the nanowires is adjacent to the first portion of the nanowires; embedding a third portion of the nanowires in a first dielectric layer, wherein the third portion of the nanowires is adjacent to the second portion of the nanowires; embedding a fourth portion of the nanowires in a second masking layer, wherein the fourth portion of the nanowires is adjacent to the third portion of the nanowires; removing the shell semiconducting region from a fifth portion of the nanowires, wherein the fifth portion of the nanowires is adjacent to the fourth portion of the nanowires; removing the second masking layer from the fourth portion of nanowires; embedding at least some of the fifth portion of the nanowires in a second dielectric layer; embedding at least some of the fifth portion of the nanowires in a second conducting layer, wherein the second conducting layer is on top of the second dielectric layer; removing the first masking layer; and removing the substrate.

Another aspect of the invention involves a method that includes: forming an array of nanowires on a substrate. The method also includes, for a plurality of nanowires in the array of nanowires: forming a core semiconducting region with a first type of doping, and forming a shell semiconducting region with a second type of doping. The method also includes: embedding a first portion of the nanowires in a masking layer; removing the shell semiconducting region from a second portion of the nanowires, wherein the second portion of the nanowires is adjacent to the first portion of the nanowires; embedding at least some of the second portion of the nanowires in a dielectric layer, wherein the dielectric layer is on top of the masking layer; removing the substrate; removing the masking layer; embedding at least some of the second portion of nanowires in a first conducting layer, wherein the first conducting layer is on top of the dielectric layer; and embedding at least some of the first portion of nanowires in a second conducting layer, wherein the second conducting layers is adjacent to the bottom of the dielectric layer.

Another aspect of the invention involves a method that includes: forming an array of nanowires on a substrate. The method also includes, for a plurality of nanowires in the array of nanowires: forming a core semiconducting region with a first type of doping, and forming a shell semiconducting region with a second type of doping. The method also includes: embedding the array of nanowires in a dielectric material; removing the substrate; removing a portion of the dielectric material from a first portion of the nanowires, thereby exposing the first portion of the nanowires; removing shell semiconducting regions in the exposed first portion of the nanowires from respective nanowires; embedding at least some of the first portion of the nanowires in a first conducting layer, wherein the first conducting layer is adjacent to a first side of the dielectric layer; removing a portion of the dielectric material from a second side of the dielectric layer, wherein the second side of the dielectric layer is opposite the first side of the dielectric layer, thereby exposing a second portion of the nanowires; and embedding at least some of the second portion of the nanowires in a second conducting layer. The second conducting layer is adjacent to the second side of the dielectric material layer.

Thus, the present invention provides nanorod-based composite structures for photovoltaic energy production and methods for making these structures. Such structures and methods are efficient, low cost, stable, and non-toxic.

### BRIEF DESCRIPTION OF THE DRAWINGS

For a better understanding of the aforementioned aspects of the invention as well as additional aspects and embodiments thereof, reference should be made to the Description of Embodiments below, in conjunction with the following drawings in which like reference numerals refer to corresponding parts throughout the figures. For clarity, features in some figures are not drawn to scale.

FIGS. 1-9 are schematic cross sections illustrating a method of making a nanorod-based composite in accordance with some embodiments.

FIGS. 10-18 are schematic cross sections illustrating a method of making a nanorod-based composite in accordance with some embodiments.

FIGS. 19-25 are schematic cross sections illustrating a method of making a nanorod-based composite in accordance with some embodiments.

FIGS. 26A-26C are schematic cross sections of an article of manufacture in accordance with some embodiments.

FIG. 27 is a schematic cross section of an article of manufacture in accordance with some embodiments.

FIG. 28 is a schematic cross section of a nanorod in accordance with some embodiments.

FIGS. 29-34 are schematic cross sections illustrating a method of making a nanorod-based composite in accordance with some embodiments.

FIG. 35A-35C are cross sections illustrating an article of manufacture in accordance with some embodiments.

FIG. 36 is a schematic cross section of an article of manufacture in accordance with some embodiments.

FIG. 37 is a schematic cross section of a nanorod in accordance with some embodiments.

FIG. 38 is a transmission electron microscope image of a portion of a single-crystalline silicon nanorod.

FIG. 39 is a transmission electron microscope image of a portion of a single-crystalline silicon nanorod.

FIG. 40 is a scanning electron microscope image of a single-crystalline silicon nanorod.

FIG. 41 is a scanning electron microscope image of a plurality of single-crystalline silicon nanorods embedded in a freestanding polymer film.

FIG. 42 is a current-voltage graph of diode behavior for a single-crystalline silicon nanorod-based composite.

### DESCRIPTION OF EMBODIMENTS

The disclosed embodiments relate to structures that use nanorod-based composites to generate photovoltaic energy and methods for making these structures. As used in the specification and claims, “nanorod” or equivalently “nanowire” refers to inorganic structures with sub-micron cross-section dimensions and aspect ratios greater than 5. For example, a cylindrical silicon-based rod with a 300 nm diameter and 10 micron length is a nanorod/nanowire.

In the following description, numerous specific details are set forth to provide a thorough understanding of the present invention. However, it will be apparent to one of ordinary skill in the art that the invention may be practiced without these particular details. In other instances, methods, procedures, and components that are well known to those of ordinary skill in the art are not described in detail to avoid obscuring aspects of the present invention.

It will be understood that when a layer is referred to as being “on top of” another layer, it can be directly on the other layer or intervening layers may also be present. In contrast, when a layer is referred to as “contacting” another layer, there are no intervening layers present.

It will also be understood that, although the terms first, second, etc. may be used herein to describe various elements, these elements should not be limited by these terms. These terms are only used to distinguish one element from another. For example, a first layer could be termed a second layer, and, similarly, a second layer could be termed a first layer, without departing from the scope of the present invention.

The terminology used in the description of the invention herein is for the purpose of describing particular embodiments only and is not intended to be limiting of the invention. As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Thus, the regions illustrated in the figures are schematic in nature and their shapes are not intended to illustrate the actual shape of a region of a device and are not intended to limit the scope of the invention.

Unless otherwise defined, all terms used in disclosing embodiments of the invention, including technical and scientific terms, have the same meaning as commonly understood by one of ordinary skill in the art to which this invention belongs, and are not necessarily limited to the specific definitions known at the time of the present invention being described. Accordingly, these terms can include equivalent terms that are created after such time. It will be further understood that terms, such as those defined in commonly used dictionaries, should be interpreted as having a meaning that is consistent with their meaning in the present specification and in the context of the relevant art and will not be interpreted in an idealized or overly formal sense unless expressly so defined herein. All publications, patent applications, patents, and other references mentioned herein are incorporated by reference in their entirety.

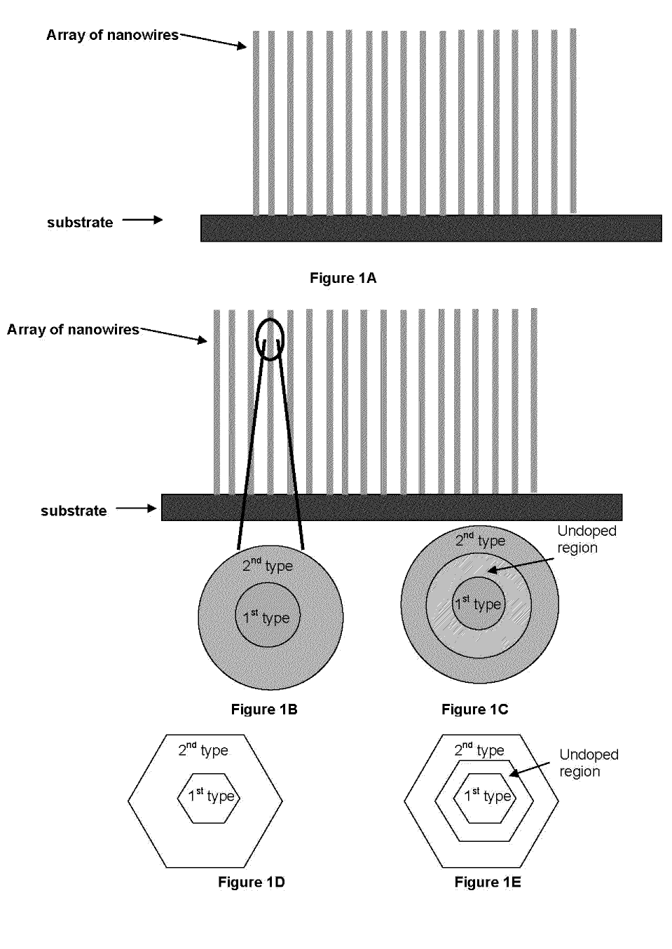

FIGS. 1-9 are schematic cross sections illustrating a method of making a nanorod-based composite in accordance with some embodiments.

An array of nanowires is formed on a substrate (FIG. 1A). In some embodiments, the array of nanowires is formed by vapor-liquid-solid (VLS) growth (e.g., as described further below). In some embodiments, the array of nanowires is formed by wet etching the substrate.

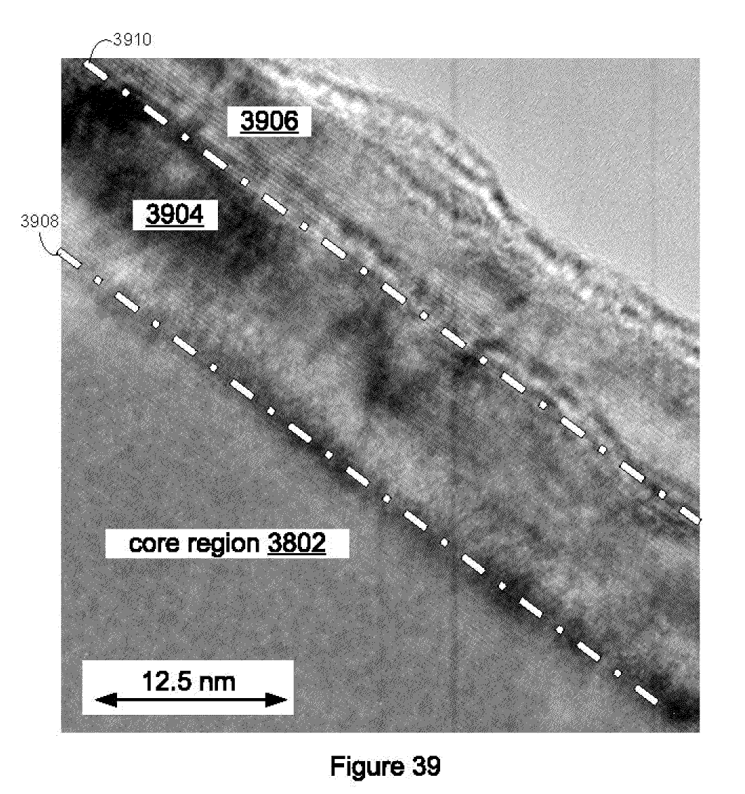

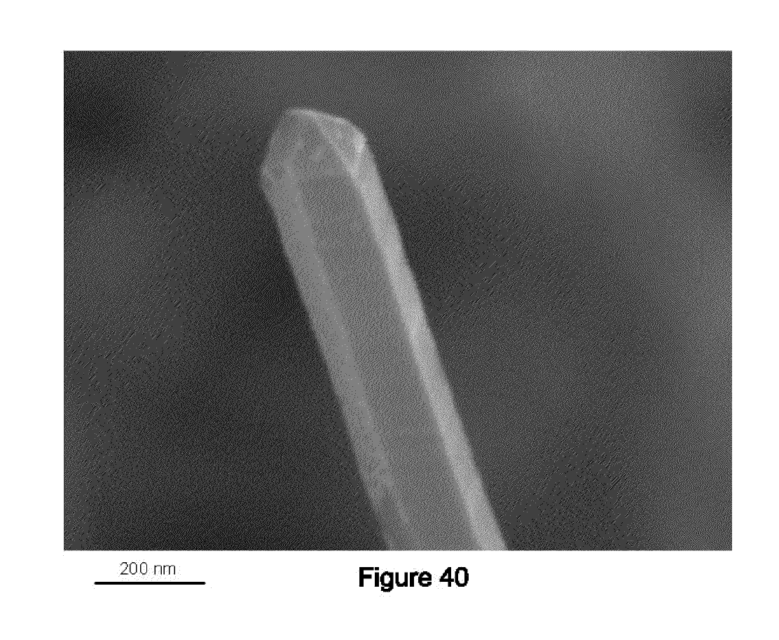

For a plurality of nanowires in the array of nanowires: a core semiconducting region is formed with a first type of doping and a shell semiconducting region is formed with a second type of doping (e.g., FIG. 1B and FIG. 1D). In some embodiments, an undoped region is formed between the core semiconducting region and the shell semiconducting region (e.g., FIG. 1C, FIG. 1E, and FIG. 39). In some embodiments, the nanowires have a cylindrical shape with a circular cross section (e.g., FIG. 1B and FIG. 1C). In some embodiments, the nanowires have a polygonal cross section (e.g., FIG. 1D, FIG. 1E, and FIG. 40).

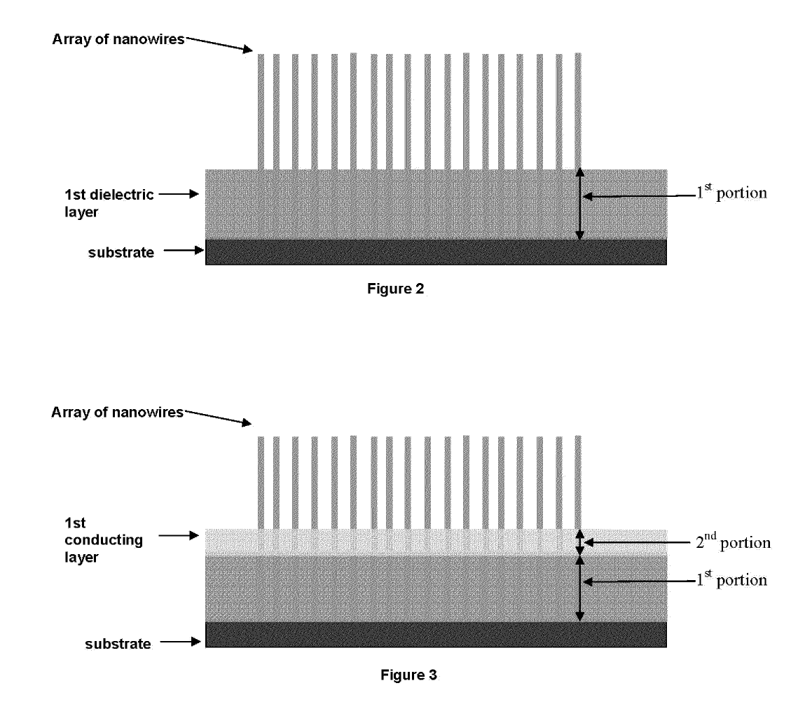

A first portion of the nanowires is embedded in a first dielectric layer (FIG. 2). In some embodiments, the first dielectric layer comprises a polymer. In some embodiments, the first dielectric layer comprises polydimethylsiloxane (PDMS). In some embodiments, the first dielectric layer comprises a polyxylylene polymer, such as Parylene.

A second portion of the nanowires is embedded in a first conducting layer (FIG. 3). The second portion of the nanowires is adjacent to the first portion of the nanowires (FIG. 3). In some embodiments, the first conducting layer comprises a metal. In some embodiments, the first conducting layer comprises indium tin oxide (ITO). In some embodiments, the first conducting layer comprises Ti, Au, or Pd.

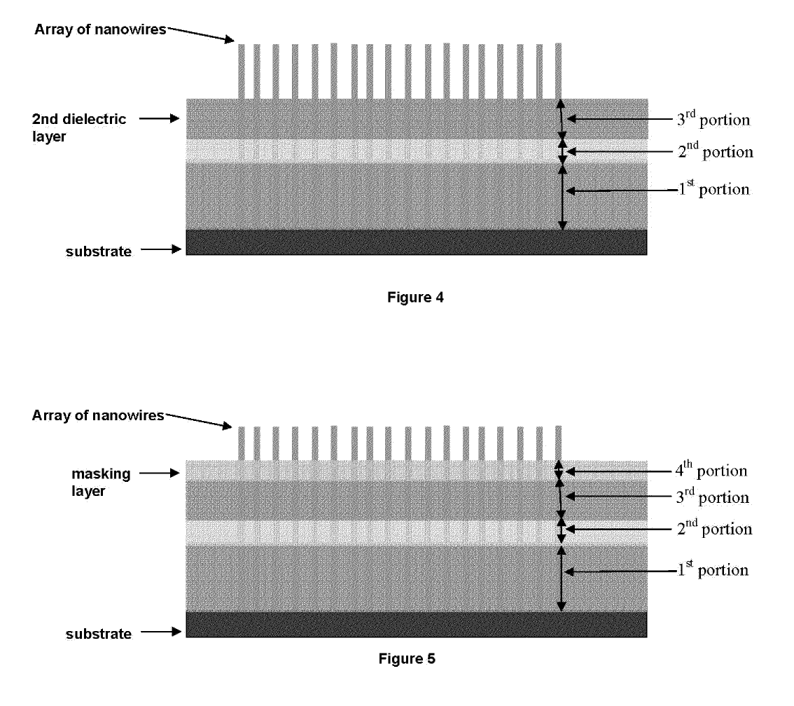

A third portion of the nanowires is embedded in a second dielectric layer (FIG. 4). The third portion of the nanowires is adjacent to the second portion of the nanowires (FIG. 4). In some embodiments, the second dielectric layer comprises a polymer. In some embodiments, the second dielectric layer comprises PDMS. In some embodiments, the second dielectric layer comprises a polyxylylene polymer, such as Parylene.

A fourth portion of the nanowires is embedded in a masking layer (FIG. 5). The fourth portion of the nanowires is adjacent to the third portion of the nanowires (FIG. 5). In some embodiments, the masking layer is photoresist.

The shell semiconducting region is removed from a fifth portion of the nanowires (FIG. 6). The fifth portion of the nanowires is adjacent to the fourth portion of the nanowires (FIG. 6).

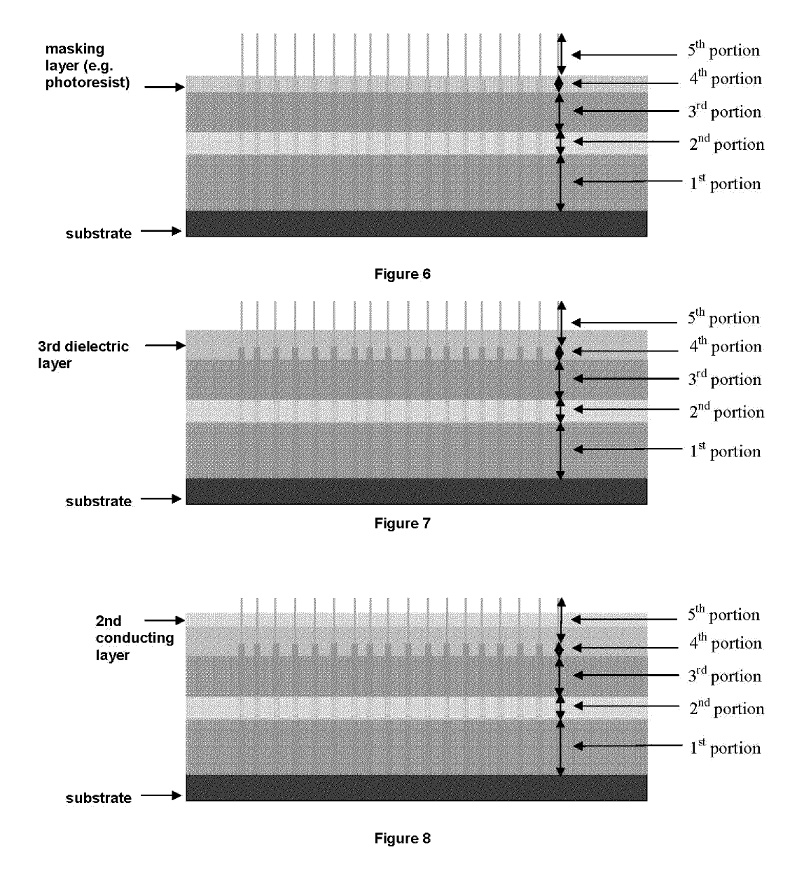

The masking layer is removed from the fourth portion of nanowires (FIG. 7). At least some of the fifth portion of the nanowires is embedded in a third dielectric layer (FIG. 7). In some embodiments, the third dielectric layer comprises a polymer. In some embodiments, the third dielectric layer comprises PDMS. In some embodiments, the third dielectric layer comprises a polyxylylene polymer, such as Parylene.

At least some of the fifth portion of the nanowires is embedded in a second conducting layer (FIG. 8). The second conducting layer is on top of the third dielectric layer (FIG. 8). In some embodiments, the second conducting layer comprises a metal. In some embodiments, the second conducting layer comprises ITO.

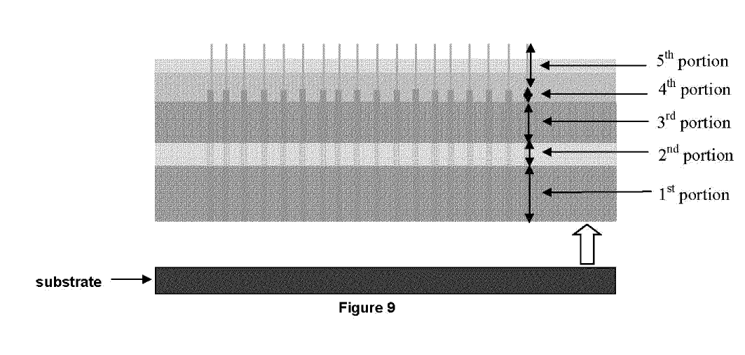

The substrate is removed (FIG. 9).

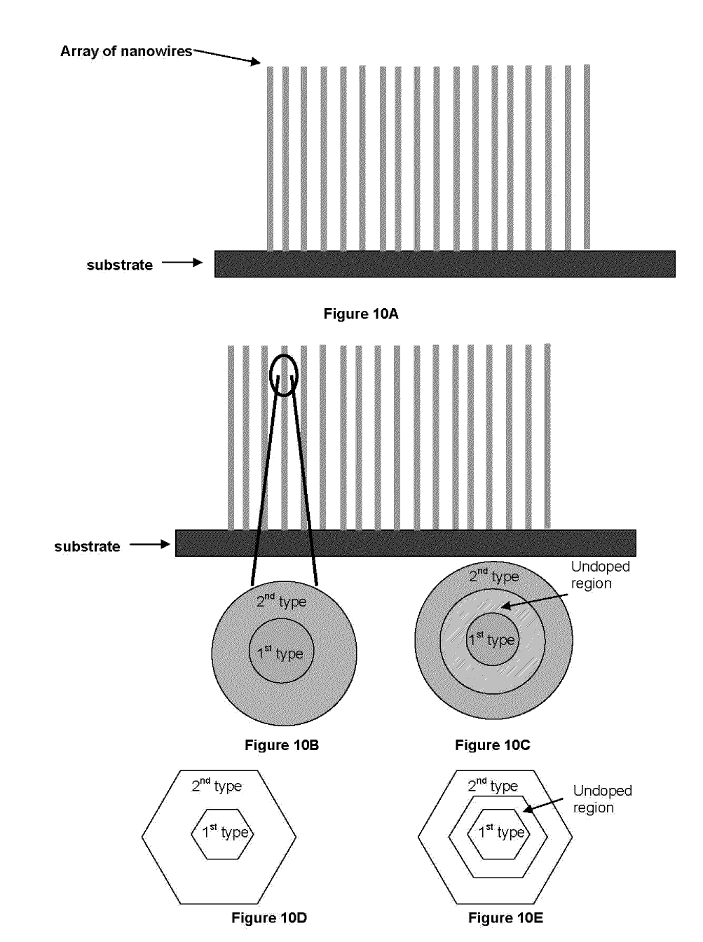

FIGS. 10-18 are schematic cross sections illustrating a method of making a nanorod-based composite in accordance with some embodiments.

An array of nanowires is formed on a substrate (FIG. 10A). In some embodiments, the array of nanowires is formed by VLS (e.g., as described further below). In some embodiments, the array of nanowires is formed by wet etching the substrate.

For a plurality of nanowires in the array of nanowires: a core semiconducting region is formed with a first type of doping; and a shell semiconducting region is formed with a second type of doping (e.g., FIG. 10B and FIG. 10D). In some embodiments, an undoped region is formed between the core semiconducting region and the shell semiconducting region (e.g., FIG. 10C, FIG. 10E, and FIG. 39). In some embodiments, the nanowires have a cylindrical shape with a circular cross section (e.g., FIG. 10B and FIG. 10C). In some embodiments, the nanowires have a polygonal cross section (e.g., FIG. 10D, FIG. 10E, and FIG. 40).

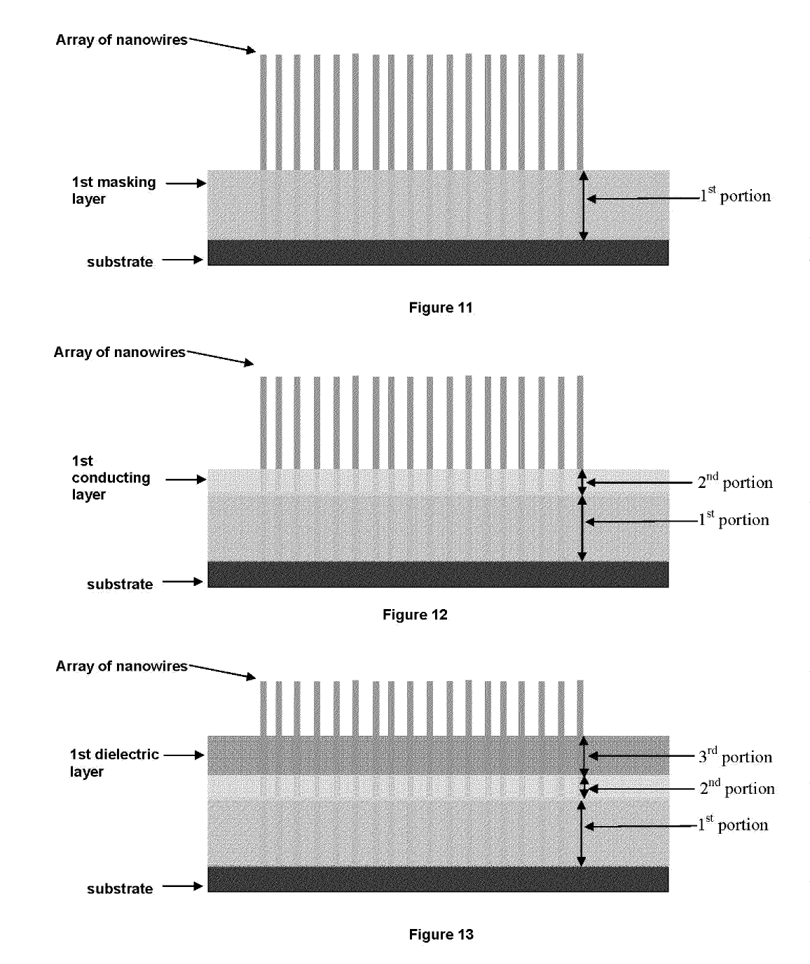

A first portion of the nanowires is embedded in a first masking layer (FIG. 11). In some embodiments, the masking layer is photoresist.

A second portion of the nanowires is embedded in a first conducting layer (FIG. 12). The second portion of the nanowires is adjacent to the first portion of the nanowires (FIG. 12).

A third portion of the nanowires is embedded in a first dielectric layer (FIG. 13). The third portion of the nanowires is adjacent to the second portion of the nanowires (FIG. 13). In some embodiments, the first dielectric layer comprises a polymer. In some embodiments, the first dielectric layer comprises polydimethylsiloxane (PDMS). In some embodiments, the first dielectric layer comprises a polyxylylene polymer, such as Parylene.

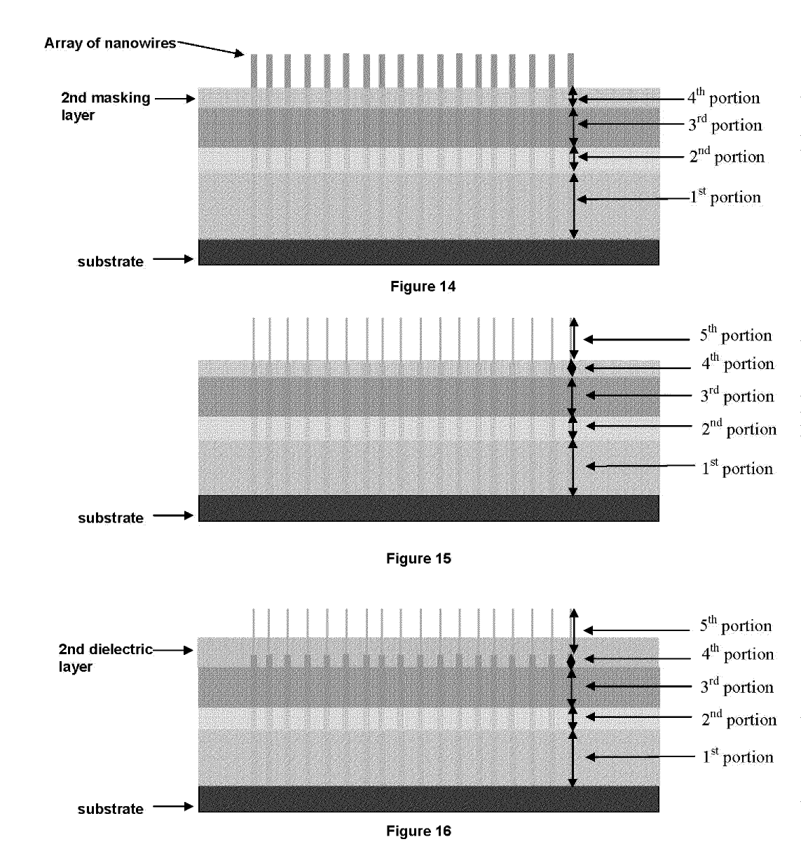

A fourth portion of the nanowires is embedded in a second masking layer (FIG. 14). The fourth portion of the nanowires is adjacent to the third portion of the nanowires (FIG. 14). In some embodiments, the second masking layer is photoresist.

The shell semiconducting region is removed from a fifth portion of the nanowires (FIG. 15). The fifth portion of the nanowires is adjacent to the fourth portion of the nanowires (FIG. 15).

The second masking layer is removed from the fourth portion of nanowires (FIG. 16). At least some of the fifth portion of the nanowires is embedded in a second dielectric layer (FIG. 16). In some embodiments, the second dielectric layer comprises a polymer. In some embodiments, the first dielectric layer comprises polydimethylsiloxane (PDMS). In some embodiments, the second dielectric layer comprises a polyxylylene polymer, such as Parylene.

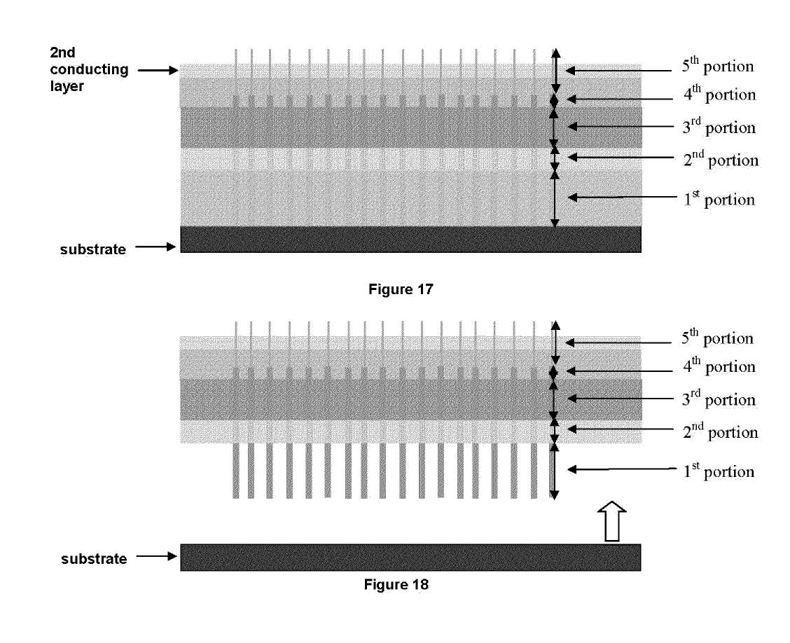

At least some of the fifth portion of the nanowires is embedded in a second conducting layer (FIG. 17). The second conducting layer is on top of the second dielectric layer (FIG. 17).

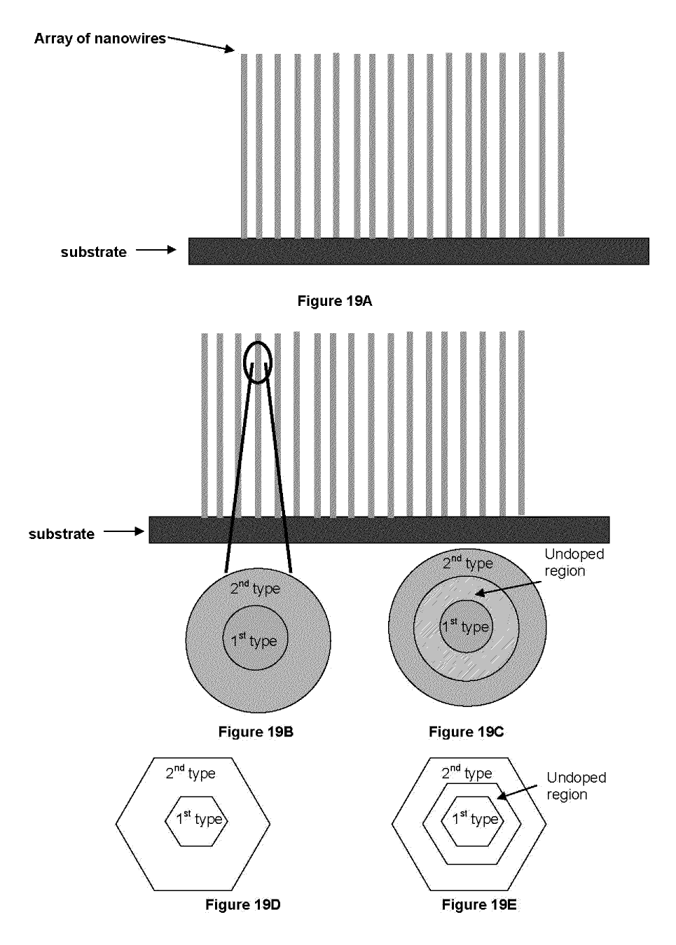

The first masking layer is removed and the substrate is removed (FIG. 18).

FIGS. 19-25 are schematic cross sections illustrating a method of making a nanorod-based composite in accordance with some embodiments.

An array of nanowires is formed on a substrate (FIG. 19A). In some embodiments, the array of nanowires is formed by VLS (e.g., as described further below). In some embodiments, the array of nanowires is formed by wet etching the substrate.

For a plurality of nanowires in the array of nanowires: a core semiconducting region is formed with a first type of doping; and a shell semiconducting region is formed with a second type of doping (e.g., FIG. 19B and FIG. 19D). In some embodiments, an undoped region is formed between the core semiconducting region and the shell semiconducting region (e.g., FIG. 19C, FIG. 19E, and FIG. 39). In some embodiments, the nanowires have a cylindrical shape with a circular cross section (e.g., FIG. 19B and FIG. 19C). In some embodiments, the nanowires have a polygonal cross section (e.g., FIG. 19D, FIG. 19E, and FIG. 40).

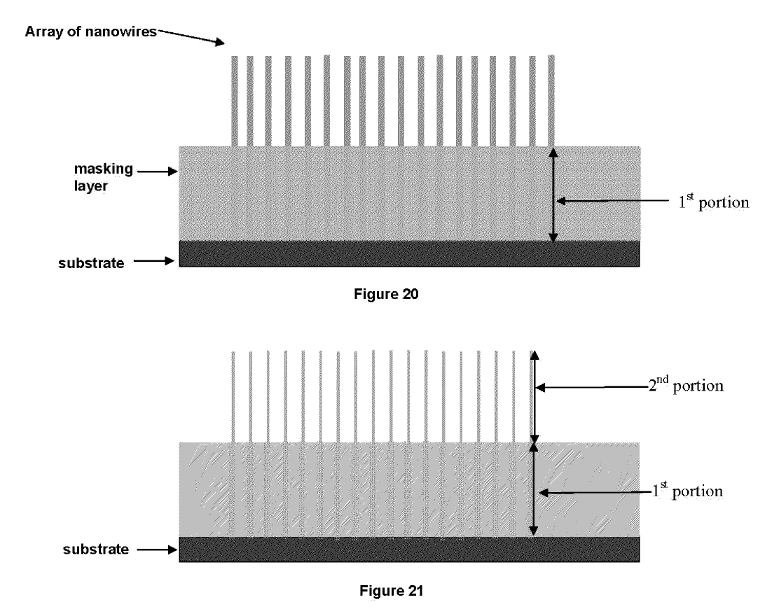

A first portion of the nanowires is embedded in a masking layer (FIG. 20). In some embodiments, the masking layer is photoresist.

The shell semiconducting region is removed from a second portion of the nanowires (FIG. 21). The second portion of the nanowires is adjacent to the first portion of the nanowires (FIG. 21).

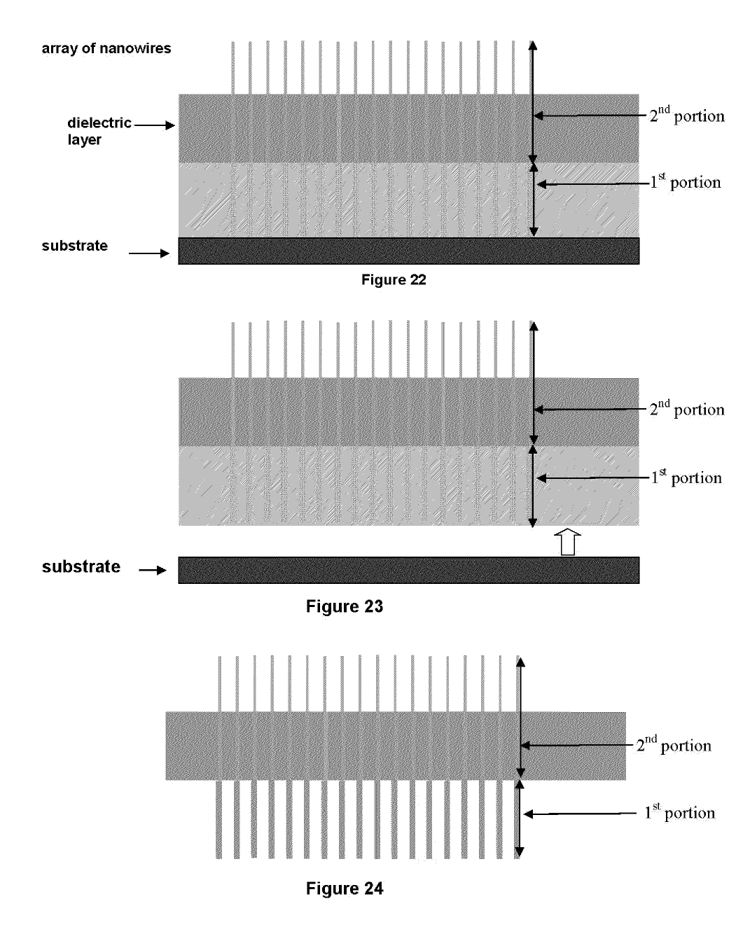

At least some of the second portion of the nanowires is embedded in a dielectric layer (FIG. 22). The dielectric layer is on top of the masking layer (FIG. 22). In some embodiments, the dielectric layer comprises a polymer. In some embodiments, the dielectric layer comprises polydimethylsiloxane (PDMS). In some embodiments, the dielectric layer comprises a polyxylylene polymer, such as Parylene.

The substrate is removed (FIG. 23).

The masking layer is removed (FIG. 24).

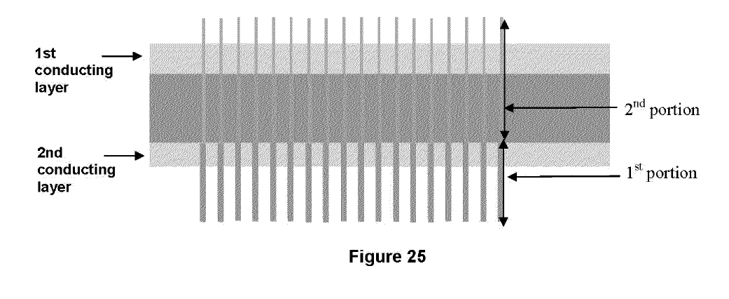

At least some of the second portion of nanowires is embedded in a first conducting layer, wherein the first conducting layer is on top of the dielectric layer (FIG. 25). At least some of the first portion of nanowires is embedded in a second conducting layer, wherein the second conducting layers is adjacent to the bottom of the dielectric layer (FIG. 25).

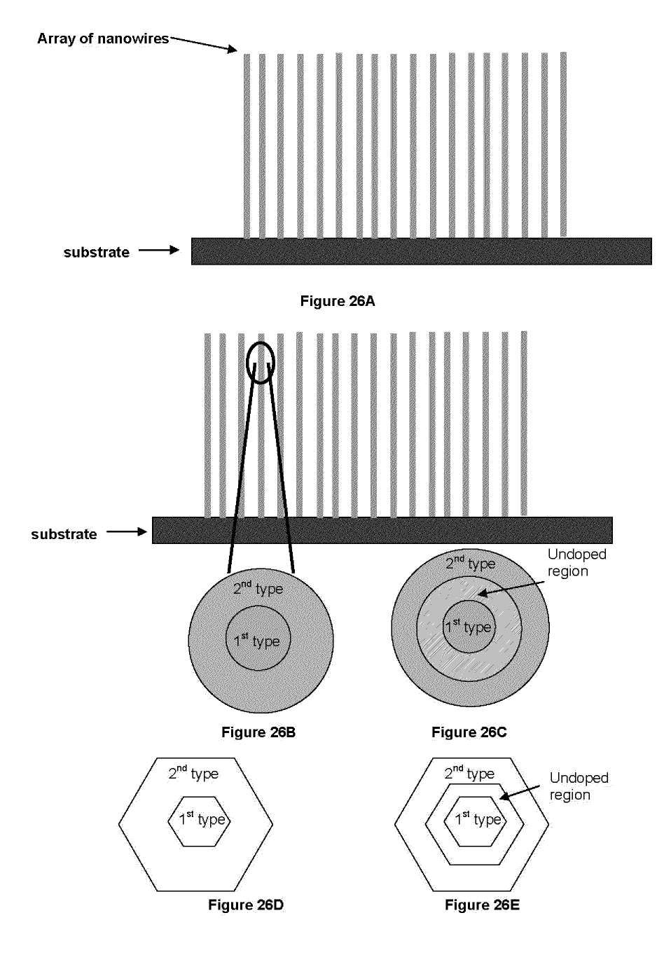

FIGS. 26-34 are schematic cross sections illustrating a method of making a nanorod-based composite in accordance with some embodiments.

An array of nanowires is formed on a substrate (FIG. 26A). In some embodiments, the array of nanowires is formed by VLS (e.g., as described further below). In some embodiments, the array of nanowires is formed by wet etching the substrate.

For a plurality of nanowires in the array of nanowires: a core semiconducting region is formed with a first type of doping; and a shell semiconducting region is formed with a second type of doping (e.g., FIG. 26B and FIG. 26D). In some embodiments, an undoped region is formed between the core semiconducting region and the shell semiconducting region (e.g., FIG. 26C, FIG. 26E, and FIG. 39). In some embodiments, the nanowires have a cylindrical shape with a circular cross section (e.g., FIG. 26B and FIG. 26C). In some embodiments, the nanowires have a polygonal cross section (e.g., FIGS. 26D, 26E, and FIG. 40).

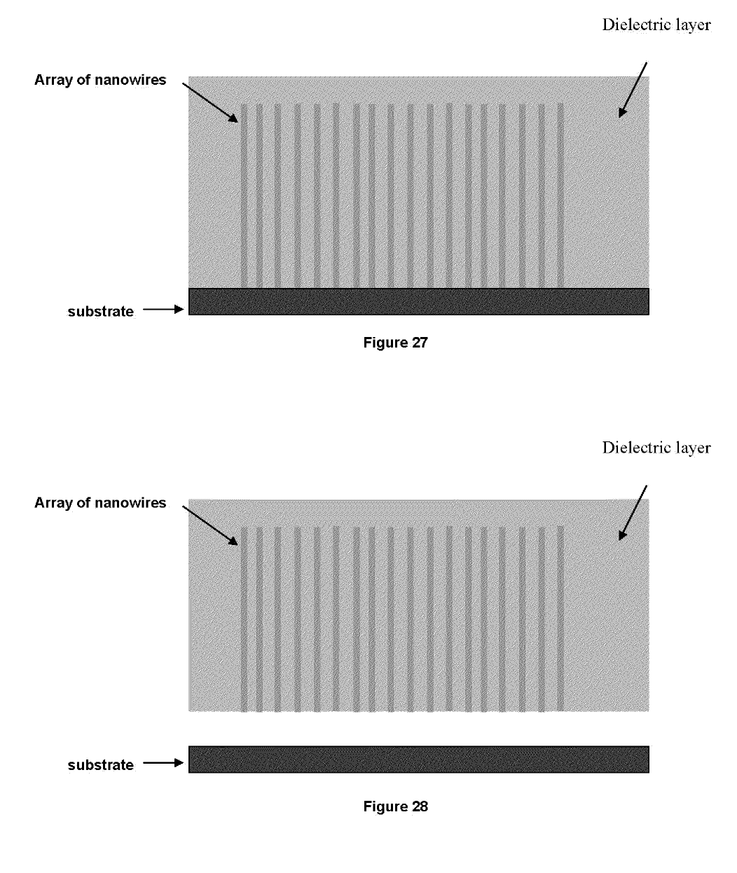

The array of nanowires is embedded in a dielectric material (FIG. 27). The tops of the nanowires are completely embedded inside the dielectric material. In some embodiments, the dielectric material comprises a polymer. In some embodiments, the dielectric material comprises polydimethylsiloxane (PDMS). In some embodiments, the dielectric material comprises a polyxylylene polymer, such as Parylene.

The substrate is removed (FIG. 28).

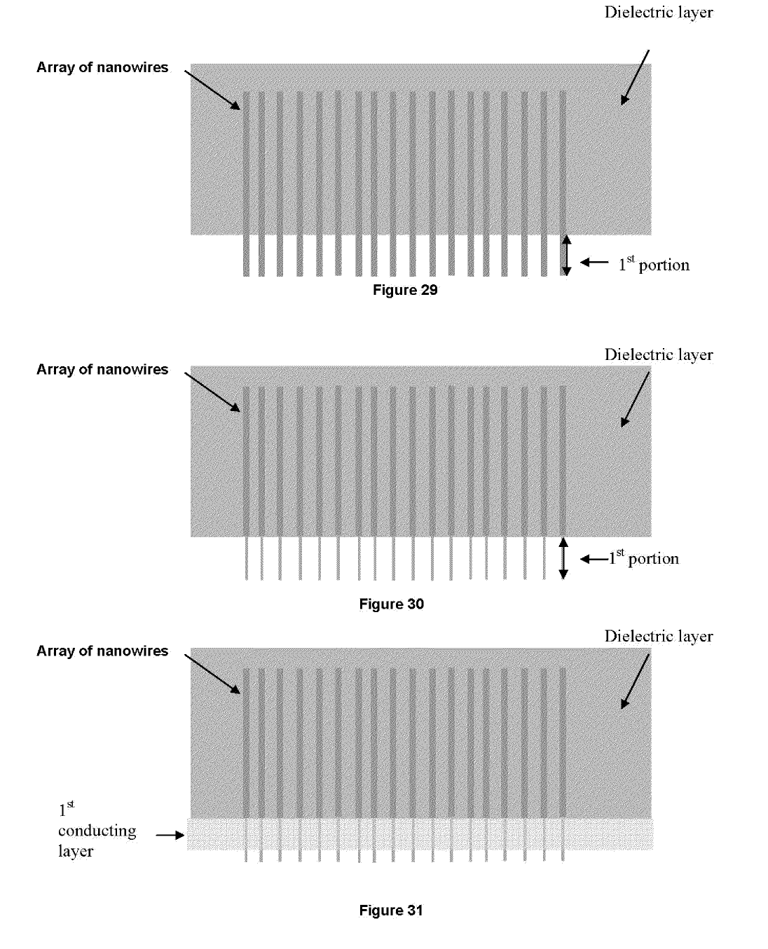

A portion of the dielectric material is removed from a first portion of the nanowires, thereby exposing the first portion of the nanowires (FIG. 29). In some embodiments, plasma etching can be used to remove a portion of the dielectric material (e.g., Parylene) without damaging the nanowires.

Shell semiconducting regions in the exposed first portion of the nanowires are removed from respective nanowires (FIG. 30).

At least some of the first portion of the nanowires is embedded in a first conducting layer (FIG. 31), e.g., by depositing the first conducting layer on the first portion of the nanowires. The first conducting layer is adjacent to a first side of the dielectric layer (FIG. 31).

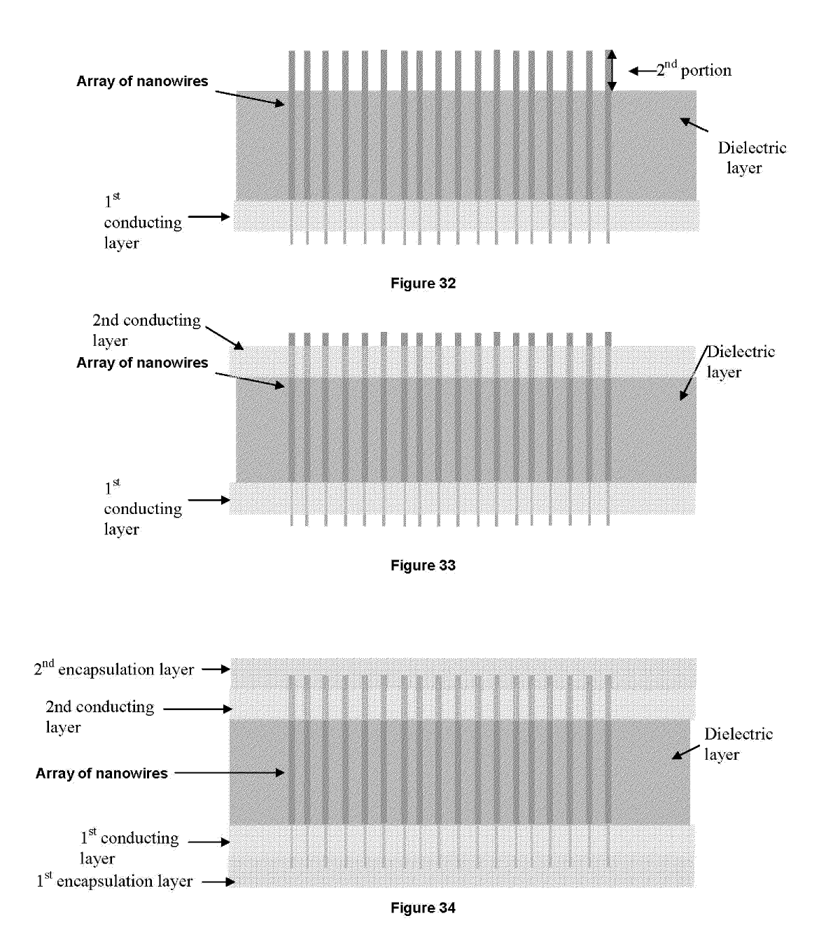

A portion of the dielectric material is removed from a second side of the dielectric layer, wherein the second side of the dielectric layer is opposite the first side of the dielectric layer (FIG. 32), thereby exposing a second portion of the nanowires. In some embodiments, the portion of dielectric material (e.g., Parylene) is removed by plasma etching.

At least some of the second portion of the nanowires is embedded in a second conducting layer (FIG. 33), e.g., by depositing the second conducting layer on the second portion of the nanowire array. The second conducting layer is adjacent to the second side of the dielectric material layer (FIG. 33).

A first encapsulation layer is deposited on the first conducting layer (FIG. 34). A second encapsulation layer is deposited on the second conducting layer (FIG. 34). In some embodiments, the encapsulation layer(s) comprise a polyurethane resin.

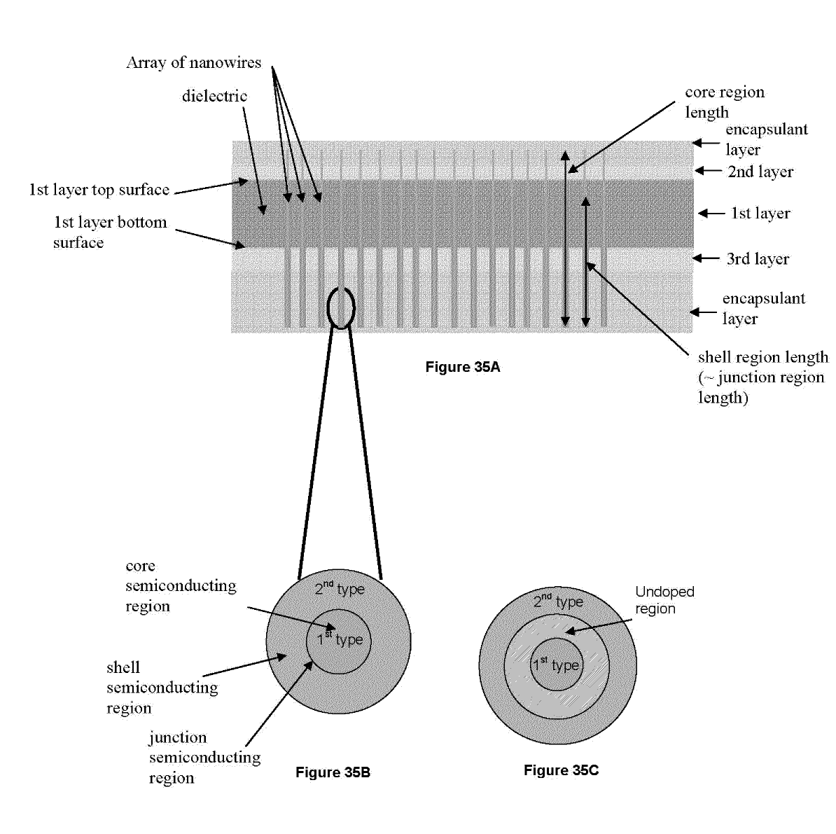

FIGS. 35A-35C are schematic cross sections of an article of manufacture in accordance with some embodiments.

The article of manufacture includes a first layer with a top surface and a bottom surface. The first layer includes an array of nanowires and a dielectric material.

The nanowires in the array of nanowires include:
a core semiconducting region with a first type of doping and a core region length;
a shell semiconducting region with a second type of doping and a shell region length; and
a junction region between the core semiconducting region and the shell semiconducting region with a junction region length (FIG. 35B).

In some embodiments, the width/diameter of the nanorods may range between 100-100 nm, 100-400 nm, 200-300 nm, or may be about 250 nm.

The first type of doping is different from the second type of doping. The shell region length is less than the core region length (FIG. 35A). The shell semiconducting region surrounds a portion of the core semiconducting region over a length of the core semiconducting region corresponding to the junction region length.

The article of manufacture also includes a second layer contacting the top surface of the first layer. The second layer comprises a conducting material.

The article of manufacture also includes a third layer contacting the bottom surface of the first layer. The third layer comprises a conducting material.

In some embodiments, the nanowire array is embedded in the dielectric material. In some embodiments, the dielectric material in the first layer comprises a polymer. In some embodiments, the dielectric material in the first layer comprises PDMS. In some embodiments, the dielectric material in the first layer comprises silicone. In some embodiments, the dielectric material comprises a polyxylylene polymer, such as Parylene.

In some embodiments, the first type of doping is p-type and the second type of doping is n-type. In some embodiments, the first type of doping is n-type and the second type of doping is p-type.

In some embodiments, the core region length may range between 1 μm-1 mm, 50-200 μm, 50-100 μm, 80-100 μm, or may be about 100 μm.

In some embodiments, the nanowire comprises silicon. In some embodiments, respective nanowires in the array of nanowires comprise single-crystalline silicon. In some embodiments, a respective single-crystalline nanowire includes a single-crystalline core semiconducting region with a first type of doping (e.g., p-type) and a single-crystalline shell semiconducting region with a second type of doping (e.g., n-type). In some embodiments, a respective single-crystalline nanowire includes a single-crystalline core semiconducting region with a first type of doping (e.g., p-type), a single-crystalline shell semiconducting region with a second type of doping (e.g., n-type), and a single-crystalline undoped region between the core semiconducting region and the shell semiconducting region (e.g., FIGS. 39 and 40).

In some embodiments, the nanowire comprises germanium. In some embodiments, the nanowire comprises silicon-germanium. In some embodiments, the nanowire comprises InGaN. In some embodiments, the nanowire comprises GaAs. In some embodiments, the nanowire comprises a III-V or II-VI semiconductor.

In some embodiments, the core region is made of a first semiconducting material and the shell region is made of a second semiconducting material that is different from the first semiconducting material. For example, the nanowire may be made with various core-shell material combinations, such as: a silicon core/germanium shell; a germanium core/silicon shell; a silicon core/III-V semiconductor shell; a silicon core/II-VI semiconductor shell; a germanium core/III-V semiconductor shell; or a germanium core/II-VI semiconductor shell.

In some embodiments, the shell region length is between 50-95% of the core region length. In some embodiments, the shell region length is between 80-90% of the core region length. In some embodiments, the shell region length is the same as or substantially the same as the junction region length.

In some embodiments, the second layer comprises a metal. In some embodiments, the second layer comprises ITO.

In some embodiments, the third layer comprises a metal. In some embodiments, the third layer comprises ITO.

In some embodiments, nanowires in the array of nanowires include an undoped region between the core semiconducting region and the shell semiconducting region (e.g., FIGS. 35C and 39).

In some embodiments, the article of manufacture includes an encapsulant layer on top of the second layer. In some embodiments, the article of manufacture includes an encapsulant layer on top of the third layer. In some embodiments, the article of manufacture includes an encapsulant layer on top of both the second layer and the third layer.

In some embodiments, the article of manufacture includes a polymer encapsulant layer on top of the second layer. In some embodiments, the article of manufacture includes a polymer encapsulant layer on top of the third layer. In some embodiments, the article of manufacture includes a polymer encapsulant layer on top of both the second layer and the third layer. In some embodiments, the polymer encapsulant layer(s) comprise a polyurethane resin.

In some embodiments, a freestanding multi-layer composite includes a first layer with a top surface and a bottom surface. The first layer includes an array of nanowires and a dielectric material. The nanowires in the array of nanowires include:
a core semiconducting region with a first type of doping and a core region length;
a shell semiconducting region with a second type of doping and a shell region length; and
a junction region between the core semiconducting region and the shell semiconducting region with a junction region length.

The first type of doping is different from the second type of doping. The shell region length is less than the core region length. The shell semiconducting region surrounds a portion of the core semiconducting region over a length of the core semiconducting region corresponding to the junction region length.

The freestanding multi-layer composite includes a second layer contacting the top surface of the first layer comprising a conducting material, and a third layer contacting the bottom surface of the first layer comprising a conducting material.

Nanorod-based composites enable multiple layers of thin film solar cells to be easily stacked, without the lattice matching problems that traditional multi-junction solar cell manufacturers face. By stacking up multiple freestanding composite films, the efficiency can be increased. Different films can contain different semiconductor materials with different bandgaps to maximize the adsorption of sunlight. The core-shell structures in the different films in the stack can also vary in terms of length, density, layer thickness, core-shell switch, etc.

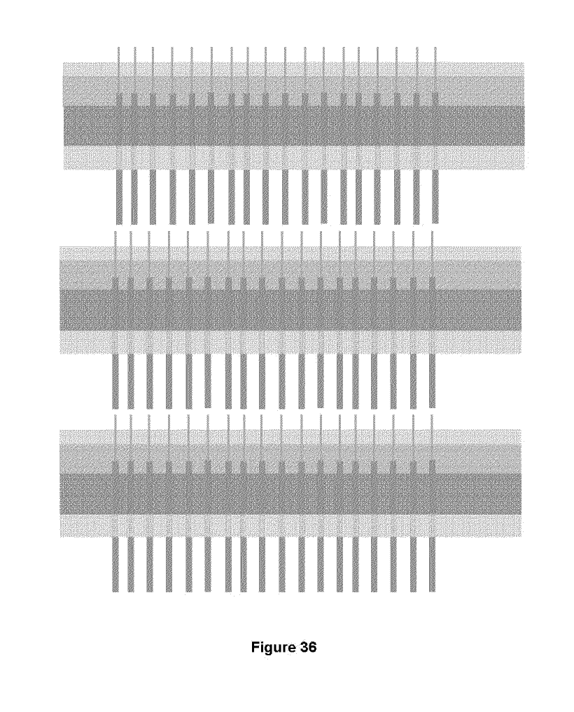

FIG. 36 is a schematic cross section of an article of manufacture in accordance with some embodiments. The article of manufacture includes a freestanding stack of composite films. At least some of the composite films in the stack of composite films include a first layer with a top surface and a bottom surface. The first layer includes an array of nanowires and a dielectric material. The nanowires in the array of nanowires include:
a core semiconducting region with a first type of doping and a core region length;
a shell semiconducting region with a second type of doping and a shell region length; and
a junction region between the core semiconducting region and the shell semiconducting region with a junction region length.

The first type of doping is different from the second type of doping. The shell region length is less than the core region length. The shell semiconducting region surrounds a portion of the core semiconducting region over a length of the core semiconducting region corresponding to the junction region length.

At least some of the composite films in the stack of composite films also include a second layer contacting the top surface of the first layer comprising a conducting material, and a third layer contacting the bottom surface of the first layer comprising a conducting material.

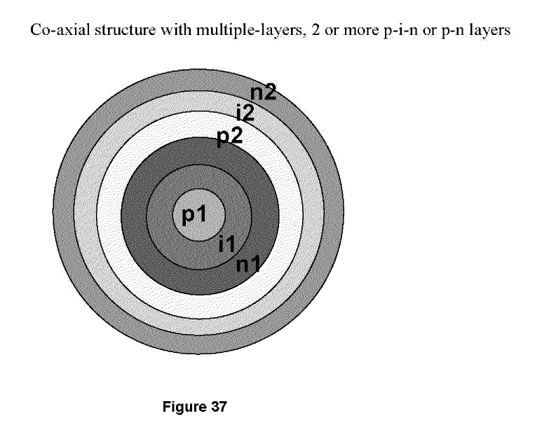

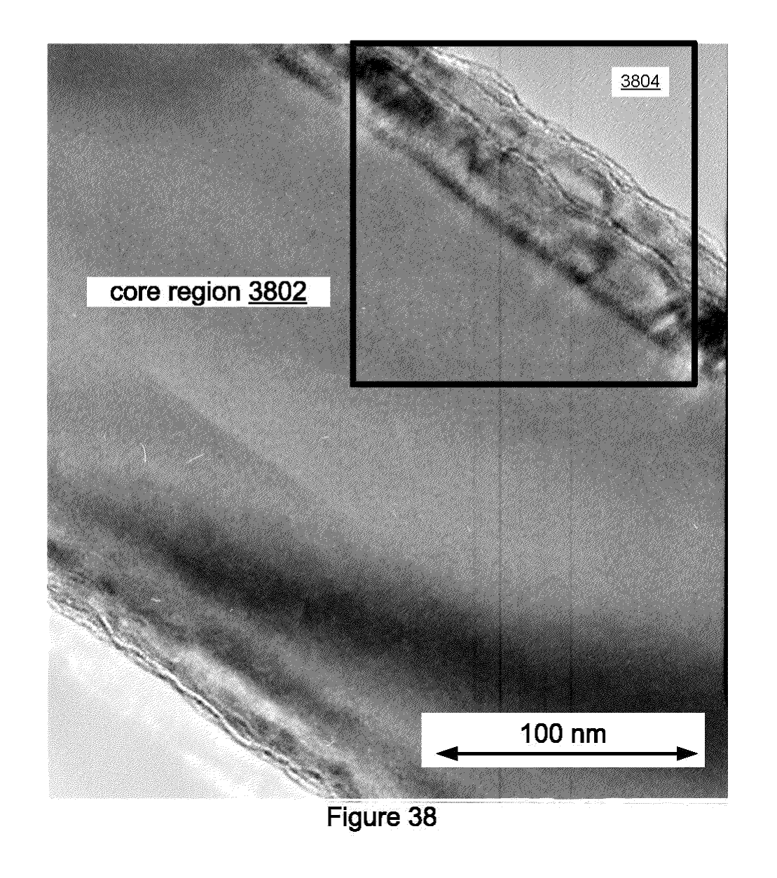

FIG. 37 is a schematic cross section of a nanorod in accordance with some embodiments. In FIG. 37, the nanorod has a co-axial structure with multiple layers, such as two or more p-i-n or p-n layers.

As noted above, in some embodiments, the nanorods are formed using a vapor-liquid-solid (VLS) growth process. In some embodiments, the nanorods are formed in the following manner.

A thin catalyst layer is formed on a substrate. For example, a <111> silicon substrate is coated with a thin layer of gold (e.g., a 5 nm-thick layer) or a layer of nanometer-size gold colloids (e.g., a 150-200 nm-thick layer). In some embodiments, a gold alloy may be used as the catalyst. In some embodiments, other metals such as nickel, copper or alloys thereof may be used as the catalyst.

In some embodiments, after deposition of the thin layer of gold (or other metal), the substrate with the metal layer is annealed. For a gold film on <111> silicon, the anneal may be performed at 400-700° C., or more preferably at 550-650° C. In some embodiments, the anneal is performed in a flowing hydrogen ambient. For example, a <111> silicon substrate with a 5 nm-thick gold catalyst layer may be annealed at 600° C. for 30 minutes. This anneal breaks up the thin metal layer into isolated catalyst particles for VLS growth.

In some embodiments, the core semiconducting region for a respective nanorod is formed by flowing silane, hydrogen, and diborane (for p-type doping of the core region) over the annealed <111> silicon substrate in a CVD chamber at 400-500° C. Exemplary processing parameters are:
460° C. growth temperature
40-100 torr total pressure (e.g., 50 torr)
50 sccm 2% silane (with the balance argon or another inert gas)
10 sccm hydrogen
10 sccm 100 ppm diborane (with the balance argon or another inert gas)
   For these processing parameters, the nanorods grow at about 1.0-1.5 μm/minute.

In some embodiments, an undoped semiconducting region for a respective nanorod is formed adjacent to the core semiconducting region by stopping the silane and diborane flows, increasing the CVD chamber temperature (e.g., to 640° C.), and then flowing 10 sccm 2% silane (with the balance argon or another inert gas) and 60 sccm hydrogen at 640° C. and 50 torr total pressure until the desired undoped semiconducting region thickness is reached.

In some embodiments, a shell semiconducting region for a respective nanorod is formed adjacent to the undoped semiconducting region (or adjacent to the core semiconducting region if no undoped semiconducting region is present) by flowing 10 sccm 2% silane (with the balance argon or another inert gas), 5 sccm 100 ppm phosphine (with the balance argon or another inert gas), and 60 sccm hydrogen at 640° C. and 50 torr total pressure until the desired shell semiconducting region thickness is reached.

The nanorods are then allowed to cool (e.g., in flowing hydrogen).

The preceding processing parameters are merely exemplary. Given these parameters, a person of ordinary skill in the art would be able to make adjustments to these parameters to vary the length of the nanorods, and the thicknesses and doping levels in the core region, the undoped region (if present), and the shell region.

FIG. 38 is a transmission electron microscope image of a portion of a single-crystalline silicon nanorod. The nanorod was made using the VLS growth process described above. The portion of the image in box 3804 is enlarged further in FIG. 39.

FIG. 39 is a transmission electron microscope image of a portion of a single-crystalline silicon nanorod. A single-crystalline undoped semiconducting region 3904 is adjacent to the core semiconducting region 3802. (Line 3908 has been added to the image to indicate the boundary between core region 3802 and the undoped region 3904.) In turn, a single-crystalline shell semiconducting region 3906 is adjacent to the undoped semiconducting region 3804. (Line 3910 has been added to the image to indicate the boundary between undoped region 3904 and the shell region 3906.) Continuous fringes that correspond to atomic planes in silicon are evident in all three regions 3802, 3804, and 3906. These fringes show the single-crystalline nature of regions 3802, 3804, and 3906.

FIG. 40 is a scanning electron microscope image of a single-crystalline silicon nanorod. The nanorod was made using the VLS growth process described above. The faceting seen in the image is due to the single-crystalline nature of the nanorod and the growth conditions used.

Single-crystalline silicon nanorods are expected to have higher photon generated minority charge carrier mobilities as compared to nanorods with amorphous or polycrystalline silicon regions. Thus, composite structures that use single-crystalline silicon nanorods should produce photovoltaic devices with higher energy conversion efficiencies as compared to composites that use nanorods with amorphous or polycrystalline silicon regions.

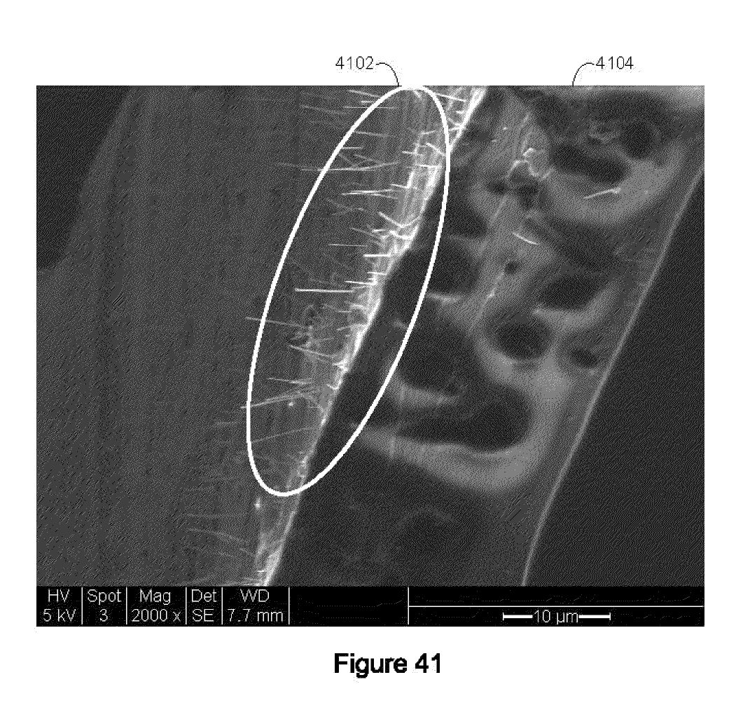

FIG. 41 is a scanning electron microscope image of a plurality of single-crystalline silicon nanorods embedded in a freestanding polymer film 4104. The nanorods are the white rods within circle 4102 (shown as a visual aid). The nanorods penetrate the film and conduct through the film. But the protrusion of the nanorods out the bottom part of the film is not visible in this image.

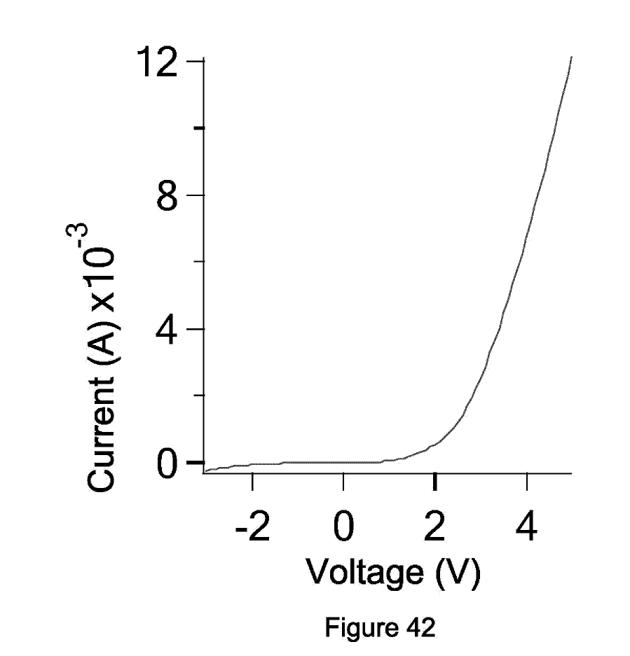

FIG. 42 is a current-voltage graph of diode behavior for a single-crystalline silicon nanorod-based composite.

The nanorod-based composites described above may be incorporated into photovoltaic energy conversion devices and systems. Exposing the composites to sunlight will generate electricity via the photovoltaic effect.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the invention and its practical applications, to thereby enable others skilled in the art to best utilize the invention and various embodiments with various modifications as are suited to the particular use contemplated.

What is claimed is:

1. An article of manufacture, comprising:
a first layer with a top surface and a bottom surface comprising an array of nanowires and a dielectric material; wherein nanowires in the array of nanowires include:
a core semiconducting region with a first type of doping and a core region length;
a shell semiconducting region with a second type of doping and a shell region length; and
a junction region between the core semiconducting region and the shell semiconducting region with a junction region length;
wherein the first type of doping is different from the second type of doping;
wherein the shell region length is less than the core region length;
wherein the shell semiconducting region surrounds a portion of the core semiconducting region over a length of the core semiconducting region corresponding to the junction region length;
a second layer contacting the top surface of the first layer comprising a conducting material; and
a third layer contacting the bottom surface of the first layer comprising a conducting material.

2. The article of manufacture of claim 1, wherein the nanowire array is embedded in the dielectric material.

3. The article of manufacture of claim 1, wherein the dielectric material in the first layer comprises a polymer.

4. The article of manufacture of claim 1, wherein the dielectric material in the first layer comprises a polyxylylene polymer.

5. The article of manufacture of claim 1, wherein the dielectric material in the first layer comprises Parylene.

6. The article of manufacture of claim 1, wherein the first type of doping is p-type and the second type of doping is n-type.

7. The article of manufacture of claim 1, wherein the first type of doping is n-type and the second type of doping is p-type.

8. The article of manufacture of claim 1, wherein the core region length is between 50-200 μm.

9. The article of manufacture of claim 1, wherein respective nanowires in the array of nanowires comprise single-crystalline silicon.

10. The article of manufacture of claim 1, wherein the shell region length is between 50-95% of the core region length.

11. The article of manufacture of claim 1, wherein the shell region length is between 80-90% of the core region length.

12. The article of manufacture of claim 1, wherein the shell region length is the same as or substantially the same as the junction region length.

13. The article of manufacture of claim 1, including an undoped region between the core semiconducting region and the shell semiconducting region.

14. The article of manufacture of claim 1, including an encapsulant layer on top of both the second layer and the third layer.

15. An article of manufacture, comprising: a freestanding multi-layer composite with
a first layer with a top surface and a bottom surface comprising an array of nanowires and a dielectric material; wherein nanowires in the array of nanowires include:
a core semiconducting region with a first type of doping and a core region length;
a shell semiconducting region with a second type of doping and a shell region length; and
a junction region between the core semiconducting region and the shell semiconducting region with a junction region length;
wherein the first type of doping is different from the second type of doping;
wherein the shell region length is less than the core region length;
wherein the shell semiconducting region surrounds a portion of the core semiconducting region over a length of the core semiconducting region corresponding to the junction region length;
a second layer contacting the top surface of the first layer comprising a conducting material; and
a third layer contacting the bottom surface of the first layer comprising a conducting material.

16. A method, comprising:
forming an array of nanowires on a substrate;
for a plurality of nanowires in the array of nanowires:
forming a core semiconducting region with a first type of doping;
forming a shell semiconducting region with a second type of doping;
embedding the array of nanowires in a dielectric material;
removing the substrate;
removing a portion of the dielectric material from a first portion of the nanowires, thereby exposing the first portion of the nanowires;
removing shell semiconducting regions in the exposed first portion of the nanowires from respective nanowires;
embedding at least some of the first portion of the nanowires in a first conducting layer, wherein the first conducting layer is adjacent to a first side of the dielectric layer;
removing a portion of the dielectric material from a second side of the dielectric layer, wherein the second side of the dielectric layer is opposite the first side of the dielectric layer, thereby exposing a second portion of the nanowires; and
embedding at least some of the second portion of the nanowires in a second conducting layer, wherein the second conducting layer is adjacent to the second side of the dielectric material layer.

17. The method of claim 16, including forming an undoped region between the core semiconducting region and the shell semiconducting region.

18. The method of claim 16, wherein the dielectric material comprises a polyxylylene polymer.

19. The method of claim 16, wherein the dielectric material comprises Parylene.

20. The method of claim 16, including depositing a first encapsulation layer on the first conducting layer and depositing a second encapsulation layer on the second conducting layer.
